(19) United States
(12) Patent Application Publication
(10) Pub. No.: US 2025/0141130 A1
(43) Pub. Date: May 1, 2025

(54) Electronic Component With Latching System for Securement to a DIN Rail

(71) Applicant: APPLETON GRP LLC, Rosemont, IL (US)

(72) Inventors: Ohvid B. Granaderos, Rizal (PH); Darwin A. Villanueva, Cavite (PH); Alexander Karl M. Manuel, Valenzuela City (PH); Billy Jay Y. Pagsuyoin, Laguna (PH); Archie Boy M. Magsombol, San Jose del Monte Bulacan (PH)

(21) Appl. No.: 18/498,859

(22) Filed: Oct. 31, 2023

(51) Int. Cl. H01R 9/26; H05K 7/20

(52) U.S. Cl. CPC H01R 9/2608; H05K 7/20418

(57) ABSTRACT

An apparatus having an electronic component; a latching system positioned on a rear end of the electronic component adapted for attachment to a DIN rail; wherein the latching system includes three or more upper fins and three or more lower fins extending from the rear end of the electronic component; a recess positioned between the three or more upper fins and the three or more lower fins adapted to receive the DIN rail; a slot positioned in a lower surface of the three or more upper fins adapted to receive an outer end of a first flange of the DIN rail; and an upper surface of the three or more lower fins adapted to have an outer end of the second flange of the DIN rail positioned.

### FIELD

The present disclosure relates to the field of providing a latching system for securing an electrical component to a DIN rail. More particularly, the present disclosure is directed to a latching system for securing an electrical component to a DIN rail where the latching system may provide for heat dissipation and may be integrally formed with the electrical component.

### BACKGROUND

Electrical components and housings are often secured to DIN rails positioned on an instrument rack in a control station or cabinet. DIN is an acronym for Deutsches

Institut für Normung, or the German Institute for Standardization in English. The mounting rail dimensions and specifications were first standardized by DIN and have since become accepted EN and IEC standards applicable globally. A DIN rail is basically a standard for metallic rails inside of equipment racks onto which are mounted control components such as controllers and other types of modules. DIN rails are often configured with a “top hat” geometry where the DIN rail has a flat upper surface with two legs extending downwardly and perpendicular to the flat upper surface. A flange extends outwardly and perpendicularly from each leg coplanar with the flat upper surface. In other embodiments, the flanges extend at an angle from the legs such that they are not coplanar with the flat upper surface.

DIN rails are typically made of steel, although other materials such as copper and aluminum may also be used. DIN rails can be made of a highly conductive material for purposes of heat dissipation.

In addition, prior art latching systems used to connect an electronic component to a DIN rail typically included a pair of latches mounted to a rear side of the electronic component, and perhaps a third latch positioned between the pair of latches.

Some electronic components, such as Power Supply Units (PSUs), including those with ranges from 960W weigh more than 2 kilograms. When an electronic component having a significant weight of 2 kilograms or more is secured to a DIN rail using the prior art latching systems described above, the weight can be problematic when the electronic component is subjected to vibration (often encountered in hazardous environments) which may cause the electronic component to fall off the DIN rail. Such a fall may cause undesirable damage to the electronic component, as well as undesirable equipment downtime.

In view of the foregoing, it would be desirable to provide a latching system on an electronic component suitable for securing electronic components having a significant weight of 2 kilograms or more to a DIN rail.

### SUMMARY

The present embodiments advantageously provide a latching system positioned on an end of an electronic component for securing the electronic component to the DIN rail. The latching system provides for a secure attachment of an electronic component to the DIN rail, where the electronic component has significant weight of 2 kilograms or more.

In one aspect, an apparatus is provided having an electronic component; a latching system positioned on a rear end of the electronic component adapted for attachment to a DIN rail; wherein the DIN rail has a flat upper surface with a first leg and a second leg extending downwardly from, and perpendicular to, the flat upper surface, and a first flange extends outwardly from the first leg, and a second flange extends outwardly from the second leg; wherein the latching system includes three or more upper fins and three or more lower fins extending from the rear end of the electronic component; a recess positioned between the three or more upper fins and the three or more lower fins adapted to receive the DIN rail; a slot positioned in a lower surface of each of the three or more upper fins adapted to receive an outer end of the first flange of the DIN rail; and an upper surface on the three or more lower fins adapted to have an outer end of the second flange of the DIN rail positioned thereover.

In another aspect, a system is provided having a DIN rail secured to a wall with fasteners; an electronic component secured to the DIN rail; a latching system positioned on a rear end of the electronic component attached to the DIN rail;

wherein the DIN rail has a flat upper surface with a first leg and a second leg extending downwardly from, and perpendicular to, the flat upper surface, and a first flange extends outwardly from the first leg, and a second flange extends outwardly from the second leg; wherein the latching system includes three or more upper and lower fins extending from the rear end of the electronic component; wherein a recess is positioned between the three or more upper fins and the three or more lower fins in which the DIN rail is positioned; a slot positioned in a lower surface of the three or more upper fins, the slot having an outer end of the first flange of the DIN rail positioned therein; and an upper surface in the three or more lower fins having an outer end of the second flange of the DIN rail positioned thereover.

In a further aspect, an apparatus is provided having an electronic component; a latching system positioned on a rear end of the electronic component adapted for attachment to a DIN rail; wherein the DIN rail has a flat upper surface with a first leg and a second leg extending downwardly from, and perpendicular to, the flat upper surface, and a first flange extends outwardly from the first leg, and a second flange extends outwardly from the second leg; wherein the latching system includes a central latching member secured to the rear end of the electronic component; a first plurality of upper fins extending outwardly from a first side of the central latching member; a first plurality of lower fins extending outwardly from the first side of the central latching member; a second plurality of upper fins extending outwardly from a second side of the central latching member, the second side opposite the first side; a second plurality of lower fins extending outwardly from the second side of the central latching member; a recess positioned between the plurality of upper fins and the plurality of lower fins adapted to receive the DIN rail; a slot positioned in a lower surface of each of the first and second plurality of in upper fins adapted to receive an outer end of the first flange of the DIN rail; and an upper surface in the first and second plurality of lower fins below the recess adapted to have an outer end of the second flange of the DIN rail positioned thereover.

### BRIEF DESCRIPTION OF THE FIGURES

FIG. 1A is a perspective view of electronic component 100 with a latching system.

FIG. 1B is a rear view of electronic component 100 with the latching system shown in FIG. 1A.

FIG. 1C is a side view of electronic component 100 with the latching system shown in FIGS. 1A and 1B.

FIG. 2A is a perspective view of electronic component 200 with a latching system.

FIG. 2B is a rear view of electronic component 200 with the latching system shown in FIG. 2A.

FIG. 2C is a side view of electronic component 200 with the latching system shown in FIGS. 2A and 2B.

FIG. 3 is a perspective view of electronic component 300 secured to DIN rail 310.

FIG. 4 is a side view of DIN rail 310.

### DETAILED DESCRIPTION

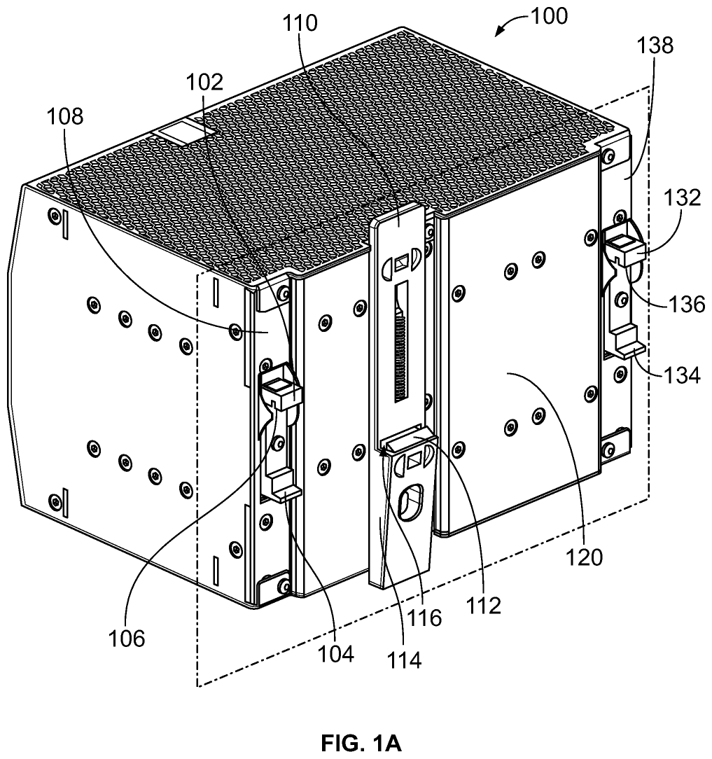

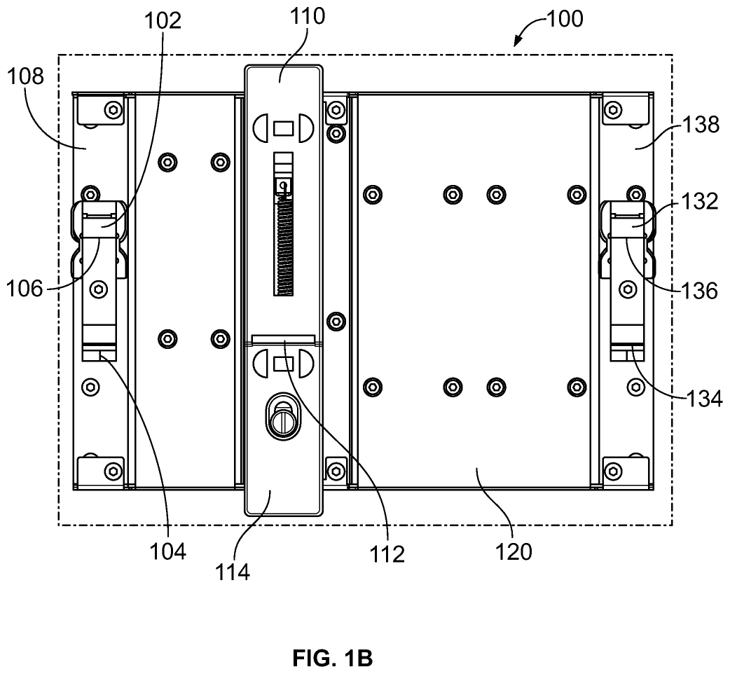

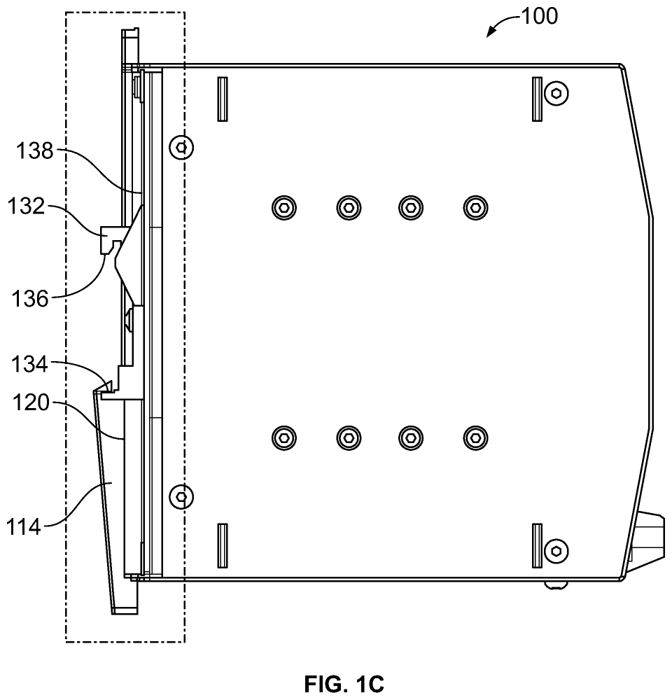

FIG. 1A is a perspective view of prior art electronic component 100 with a latching system. FIG. 1B is a rear view of electronic component 100 with the latching system shown in FIG. 1A. FIG. 1C is a side view of electronic component 100 with the latching system shown in FIGS. 1A and 1B.

Electronic component 100 includes a rear end 120. A latching system used to latch electronic component 100 to a DIN rail is shown in FIGS. 1A-1C. The latching system includes latching members 102, 132 extending outwardly from opposite sides of rear end 120. The latching system further includes a latching member 110 centrally positioned between latching members 102, 132.

Latching member 102 is removably secured to left end 108 of rear end 120 and latching member 132 is removably secured to right end 138 of rear end 120. A slot 106 is positioned in an upper end of latching member 102. Slot 106 is adapted to receive an upper flange of a DIN rail. In addition, latching member 102 also includes a lower end having an upper surface onto which a lower end of the DIN rail is positioned. Similarly, a slot 136 is positioned in an upper end of latching member 132. Slot 136 is adapted to receive an upper flange of a DIN rail. In addition, latching member 132 also includes a lower end having an upper surface over which a lower end of the DIN is positioned.

In addition, central latching member 110 is removably secured to rear end 120. Central latching member 110 includes a lower section 114 having a ramp 112 with a slot 116 positioned between a vertical surface at the end of the ramp 112 and a back wall of central latching member 110. Slot 116 is configured to receive a lower flange of the DIN rail to help secure the electronic component 100 to the DIN rail. Importantly, latching member 110 does not include an upper slot or other geometry to contain or secure the upper flange of the DIN rail.

Prior art electronic component 100 includes a latching system having latching members 102, 132 on opposite ends of rear end 120, and a centrally located latching member 110. Such a latching system only includes two points of securement for the upper flange of the DIN rail in slots 106 and 136 of latching members 102 and 132. As a result, if the electronic component 100 has a significant weight, such as 2 kilograms or more, when the electronic component 100 experiences vibrations, the electronic component 100 may disengage from the DIN rail and fall off the DIN rail. An undesirable disengagement and fall from the DIN rail may damage the electronic component 100, create downtown, or perhaps even injury to any item or individual that is contacted during the fall.

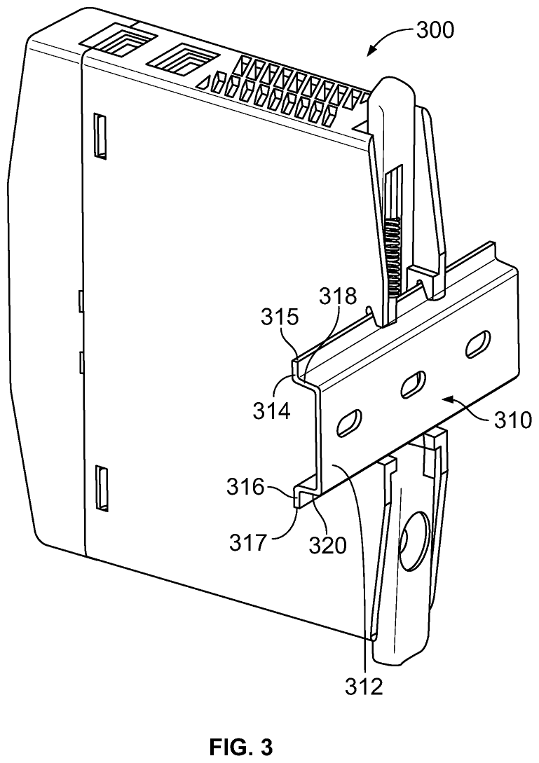

An alternate prior art electronic component 300 is shown in FIG. 3 attached to DIN rail 310. Electronic component 300 also only includes two upper securement points for upper or first flange 314 of DIN rail 310, and also suffers from the potential of electronic component 300 disengaging and falling off of DIN rail 310 when vibrations are encountered, often in hazardous environments.

In view of the foregoing, it would be desirable to provide a latching system that provides for better securement of an electronic component having significant weight (e.g., 2 kilograms or more) when vibrations are sustained.

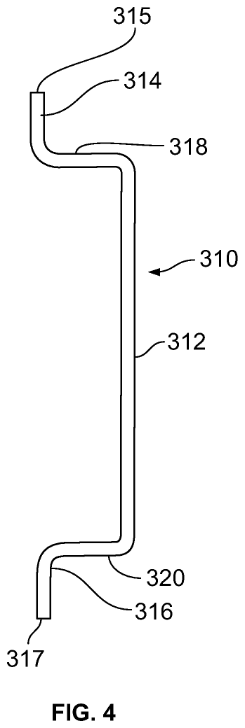

DIN rail 310 shown in FIGS. 3 and 4 is shown with a “top hat” geometry where the DIN rail 310 has a flat upper surface 312 with two legs 318, 320 extending downwardly and perpendicular to the flat upper surface 312. An upper or first flange 314 having an outer end 315 extends outwardly and perpendicularly from leg 318 coplanar with the flat upper surface 312, and a lower or second flange 316 having an outer end 317 extends outwardly and perpendicularly from leg 320 coplanar with flat upper surface 312. In other embodiments, the flanges 314, 316 may extend at an angle from the legs 318, 320 such that they are not coplanar with the flat upper surface 312. DIN rails may have a thin thickness of 1 mm, or a thick thickness of 1.5 mm, or somewhere in between. The TS35 DIN rail has a “top hat” geometry and is available with a thin thickness of 1 mm, or a thick thickness of 1.5 mm. Other thicknesses for the DIN rail components are also possible.

DIN rail 310 may be secured to a wall of an electrical control panel or box using the holes positioned in the flat upper surface 312.

Once DIN rail 310 is secured to the wall, an electrical component, such as electrical component 100 or 200 may be secured to DIN rail 310.

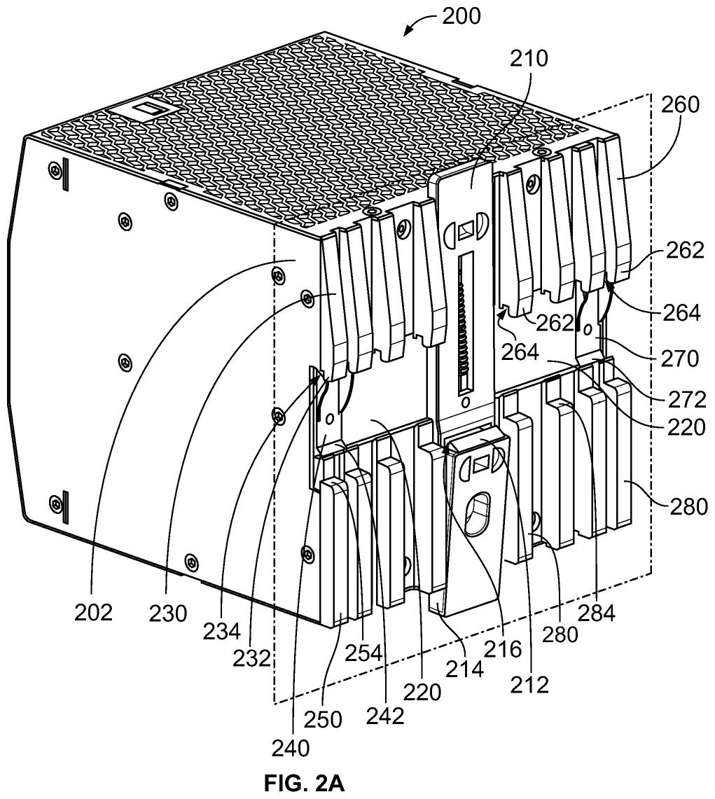

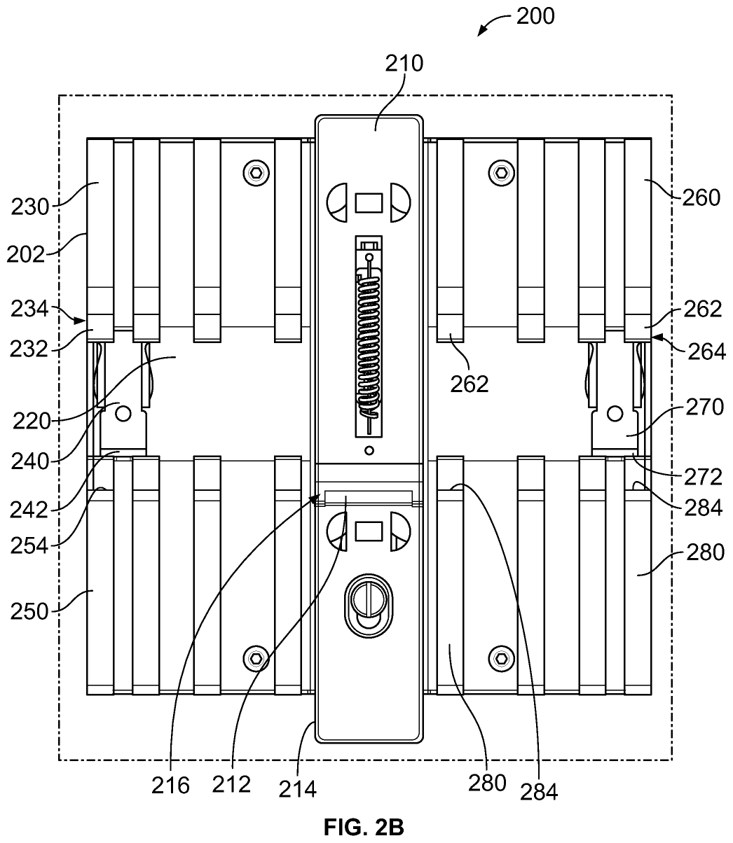

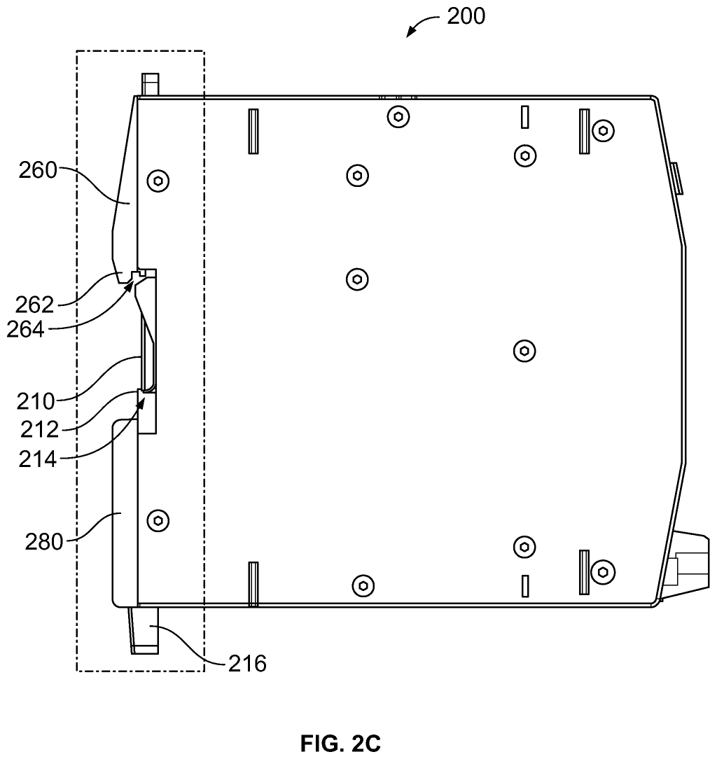

Electrical component 200 shown in FIGS. 2A-2C is designed to remain secured to DIN rail 310 even when subjected to vibrations. Electrical component 200 includes a number of other desirable features as well.

Electronic component 200 includes a plurality of fins 230, 260 extending outwardly from rear end 220. Fins 230, 260 each include an upper section 232, 262 having a slot 234, 264 positioned therein configured to receive first flange 314 of DIN rail 310. Fins 230, 260 also include a lower section 242, 272 configured to be positioned beneath second flange 316 of DIN rail 310.

The configurations of fins 230, 260 each having a slot 234, 264 in upper section 234, 264 provides for multiple points of securement of first flange 314 of DIN rail 310. The use of multiple points of securement for first flange 314 of DIN rail 310 provides for an increase in the “grip strength” of the latching system used in electronic component 200. In FIGS. 2A-2C, eight securement points in fins 230, 260 are disclosed. However, a greater or lesser number of securement points may also be used.

The outermost fins are secured to the rear end 220 of electronic component 200 as part of latching members 240, 270 similar to the system used in electronic component 100. However, the latching system of electronic component 200 advantageously includes additional fins with slots 234, 264 to provide additional securement points for first flange 314 of DIN rail 310.

Fins 230, 260 may each be secured to rear end 220 with fasteners as outermost fins are as shown in FIGS. 2A-2C. Alternately, each of fins 230, 260 may be integrally formed with rear end 220. A combination of integrally formed fins with rear end 220 and fins secured to rear end 220 with fasteners may also be used.

In addition, fins 230, 260 may be made of conductive metal material, such as aluminum, copper, etc. and provide for dissipation of heat generated from electronic component 200. Electronic component 200 includes both upper fins 230, 260 and lower fins 250, 280 with spacing in between to accommodate DIN rail 310. DIN rail 310 may also be made of a conductive metal material and fasteners used to connect DIN rail 310 may also be made of a conductive material to provide for dissipation of heat from electronic component 200 through fins 230, 250, 260, 280 through DIN rail 310 and fasteners securing DIN rail 310 to an electrical panel wall or box.

Similar to electronic component 100, electronic component 200 may include a central latching member 210 having a lower section 214 with a ramp 212 positioned on an upper surface of lower section 214. A slot 216 is positioned between a vertical surface at the end of the ramp 212 and a back wall of latching member 210. Slot 216 is configured to receive lower or second flange 316 of DIN rail 310 to help secure the electronic component 200 to the DIN rail 310. Central latching member 210 is shown positioned equidistantly from latching members 240 and 270 in FIGS. 2A-2C. However, any latching member positioned between latching members 240 and 270 constitutes a “central latching member” as long as it is positioned between latching members 240 and 270, whether or not positioned equidistantly between latching members 240 and 270.

As noted above, electronic components may be located in harsh environments which may be prone to vibration. The latching system provided in electronic component 200 provides for a secure attachment to DIN rail 310 using a multitude of securement points even when subjected to vibrations. The latching system of electronic component 310 also advantageously includes a plurality of fins 230, 250, 260, 280 that provide for dissipation of heat generated from electronic component 200. Furthermore, the latching system used in electronic component 200 may be provided on a variety of different electronic components, such as electronic component 200, power supply units (PSUs), and any other electronic component that may be secured to a DIN rail.

We claim:

1. An apparatus comprising:
an electronic component;
a latching system positioned on a rear end of the electronic component adapted for attachment to a DIN rail;
wherein the DIN rail has a flat upper surface with a first leg and a second leg extending downwardly from, and perpendicular to, the flat upper surface, and a first flange extends outwardly from the first leg, and a second flange extends outwardly from the second leg;
wherein the latching system comprises:
three or more upper fins and three or more lower fins extending from the rear end of the electronic component;
a recess positioned between the three or more upper fins and the three or more lower fins adapted to receive the DIN rail;
a slot positioned in a lower surface of each of the three or more upper fins adapted to receive an outer end of the first flange of the DIN rail; and
an upper surface on the three or more lower fins adapted to have an outer end of the second flange of the DIN rail positioned thereover.

2. The apparatus of claim 1, wherein each of the three or more upper and lower fins are comprised of a metal material.

3. The apparatus of claim 2, the metal material has a high thermal conductivity such that each of three or more upper and lower fins comprise heat-dissipating fins.

4. The apparatus of claim 1, wherein a central latching member is secured to the rear end of the electronic component between the three or more upper and lower fins.

5. The apparatus of claim 4, wherein the central latching member includes a lower section extending outwardly away from the rear end of the electronic member that includes an upper surface adapted to have an outer end of the second flange of the DIN rail positioned thereover.

6. The apparatus of claim 5, wherein the upper surface of the lower section of the central latching member includes a ramp angled upwardly towards a back wall of the central latching member;
wherein a slot is positioned between the ramp and the back wall of the central latching member; and
wherein the slot is configured to receive the outer end of the second flange of the DIN rail.

7. The apparatus of claim 6, wherein the ramp is configured to allow the outer end the second flange of the DIN rail to ride up the ramp towards the back wall of the central latching member until the second flange of the DIN rail drops into the slot and the second flange is secured between the back wall of the central latching member and an inner surface of the ramp.

8. The apparatus of claim 1, wherein at least some of the three more upper and lower fins are integrally formed with the rear end of the electronic component.

9. A system comprising:
a DIN rail secured to a wall with fasteners;
an electronic component secured to the DIN rail;
a latching system positioned on a rear end of the electronic component attached to the DIN rail;
wherein the DIN rail has a flat upper surface with a first leg and a second leg extending downwardly from, and perpendicular to, the flat upper surface, and a first flange extends outwardly from the first leg, and a second flange extends outwardly from the second leg;
wherein the latching system comprises:
three or more upper and lower fins extending from the rear end of the electronic component;
wherein a recess is positioned between the three or more upper fins and the three or more lower fins in which the DIN rail is positioned;
a slot positioned in a lower surface of the three or more upper fins, the slot having an outer end of the first flange of the DIN rail positioned therein; and
an upper surface in the three or more lower fins having an outer end of the second flange of the DIN rail positioned thereover.

10. The system of claim 9, wherein the three or more upper and lower fins are comprised of a metal material.

11. The system of claim 10, the metal material has a high thermal conductivity such that the three or more upper and lower fins comprise heat-dissipating fins.

12. The system of claim 9, wherein a central latching member is secured to the rear end of the electronic component.

13. The system of claim 12, wherein the central latching member includes a lower section extending outwardly away from the rear end of the electronic member that includes an upper surface having an outer end of the second flange of the DIN rail positioned thereover.

14. The apparatus of claim 13, wherein the upper surface of the lower section of the central latching member includes a ramp angled upwardly towards a back wall of the central latching member;
wherein a slot is positioned between the ramp and the back wall of the central latching member; and
wherein the outer end of the second flange of the DIN rail is positioned in the slot.

15. The system of claim 14, wherein the ramp is configured to allow the outer end the second flange of the DIN rail to ride up the ramp towards the back wall of the central latching member until the second flange of the DIN rail drops into the slot and the second flange is secured between the back wall of the central latching member and an inner surface of the ramp.

16. The system of claim 9, wherein at least some of the three or more upper and lower fins are integrally formed with the rear end of the electronic component.

17. An apparatus comprising:
an electronic component;
a latching system positioned on a rear end of the electronic component adapted for attachment to a DIN rail;
wherein the DIN rail has a flat upper surface with a first leg and a second leg extending downwardly from, and perpendicular to, the flat upper surface, and a first flange extends outwardly from the first leg, and a second flange extends outwardly from the second leg;
wherein the latching system comprises:
a central latching member secured to the rear end of the electronic component;
a first plurality of upper fins extending outwardly from a first side of the central latching member;
a first plurality of lower fins extending outwardly from the first side of the central latching member;
a second plurality of upper fins extending outwardly from a second side of the central latching member, the second side opposite the first side;
a second plurality of lower fins extending outwardly from the second side of the central latching member;
a recess positioned between the plurality of upper fins and the plurality of lower fins adapted to receive the DIN rail;
a slot positioned in a lower surface of each of the first and second plurality of upper fins adapted to receive an outer end of the first flange of the DIN rail; and
an upper surface in the first and second plurality of lower fins below the recess adapted to have an outer end of the second flange of the DIN rail positioned thereover.

18. The apparatus of claim 17, wherein the central latching member includes a lower section extending outwardly from the rear end of the electronic member that includes an upper surface adapted to have an outer end of the second flange of the DIN rail positioned thereover;
wherein the upper surface of the lower section of the central latching member includes a ramp angled upwardly towards a back wall of the central latching member;
wherein a slot is positioned between the ramp and the back wall of the central latching member; and
wherein the slot is configured to receive the outer end of the second flange of the DIN rail.

19. The apparatus of claim 18, wherein the ramp is configured to allow the outer end the second flange of the DIN rail to ride up the ramp towards the back wall of the central latching member until the second flange of the DIN rail drops into the slot and the second flange is secured between the back wall of the central latching member and an inner surface of the ramp.

20. The apparatus of claim 17, wherein at least some of the first and second plurality of upper and lower fins are integrally formed with the rear end of the electronic component.
